(19) United States
(12) Patent Application Publication
(10) Pub. No.: US 2026/0059699 A1
(43) Pub. Date: Feb. 26, 2026

(54) LIQUID COOLING TESTING DEVICE

(71) Applicant: King Yuan ELECTRONICS CO., LTD., Hsinchu City (TW)

(72) Inventors: Kuo-Jung Wu, Hsinchu City (TW); Shang-Jung Chiang, Hsinchu City (TW)

(73) Assignee: King Yuan ELECTRONICS CO., LTD., Hsinchu City (TW)

(21) Appl. No.: 19/021,908

(22) Filed: Jan. 15, 2025

(30) Foreign Application Priority Data
Aug. 22, 2024 (TW) 113131675

(51) Int. Cl. H05K 7/20; G01M 99/00; H05K 7/14

(52) U.S. Cl. CPC H05K 7/20272; G01M 99/008; H05K 7/1405; H05K 7/1409; H05K 7/1461; H05K 7/20254; H05K 7/20281

(57) ABSTRACT

A liquid cooling testing device includes a body, a sliding assembly, a liquid cooling plate, a test circuit board, a liquid-input coupling, a liquid-output coupling, and a cooling liquid supply module. The sliding assembly is disposed on the body. The liquid cooling plate includes a liquid inlet, a channel and a liquid outlet sequentially in communication with each other. The test circuit board is fixed on the liquid cooling plate. The cooling liquid supply module is in communication with the liquid-input coupling and the liquid-output coupling. The cooling liquid supply module supplies a cooling liquid to the channel of the liquid cooling plate through the liquid-input coupling member, and the cooling liquid supply module recycles the cooling liquid from the channel of the liquid cooling plate through the liquid-output coupling member.

### CROSS-REFERENCE TO RELATED APPLICATION

This non-provisional application claims priority under 35 U.S.C. § 119(a) to Patent Application No. 113131675 filed in Taiwan, R.O.C. on Aug. 22, 2024, the entire contents of which are hereby incorporated by reference.

### BACKGROUND

### Technical Field

The instant disclosure relates to a testing device, in particular, to a liquid cooling testing device.

### Related Art

Owing to the developments and innovations in semiconductor technology, diversity and complexity of semiconductor components are gradually increased, and manufacturing processes for the semiconductor components accordingly become more complicated. As a result, the yield of products is greatly affected, thereby increasing the manufacture costs of the semiconductor components. To ensure that product quality meets the demands, various tests are applied to the products before the products leave the factory. Therefore, people realize that the tests for semiconductor components become more important.

Along with the increase in efficiency of the semiconductor components, the semiconductor components are tested through a testing device including various testing circuit boards for computation. As a result, the heat produced from the testing circuit boards during the testing process cannot be ignored. To make sure that testing circuit boards are stable and work correctly, the heat dissipation for the testing circuit boards is important.

In testing devices known to the inventor, most of the testing devices adopt air cooling to conduct heat dissipation for the testing circuit boards. However, as to the heat dissipation for the high-efficiency testing circuit boards, air cooling gradually fails to meet the demands. On the other hand, for the liquid cooling heat dissipation modules, issues of space arrangement and complexity in assembling occur easily. As a result, the issues for the liquid cooling heat dissipation modules are to be addressed.

### SUMMARY

One or some embodiments of the instant disclosure provide a liquid cooling testing device. The liquid cooling testing device comprises a body, a slide rail component, a liquid cooling plate, a testing circuit board, a liquid-input coupling member, a liquid-output coupling member, and a cooling liquid supplying module. The slide rail component is disposed on the body. The liquid cooling plate is selectively and slidably disposed on the slide rail component, and the liquid cooling plate comprises a liquid inlet, a channel, and a liquid outlet sequentially in communication with each other. The testing circuit board is disposed on the liquid cooling plate. The cooling liquid supplying module is in communication with the liquid-input coupling member and the liquid-output coupling member. In response to that the liquid cooling plate is slidably disposed on the slide rail component, the liquid inlet is coupled to the liquid-input coupling member, and the liquid outlet is coupled to the liquid-output coupling member. The cooling liquid supplying module supplies a cooling liquid to the channel of the liquid cooling plate through the liquid-input coupling member and recycles the cooling liquid from the channel of the liquid cooling plate through the liquid-output coupling member.

Thereby, through the circulation of the cooling liquid in the liquid cooling plate, the testing circuit board can be cooled, so that the cooling efficiency of the testing circuit board can be enhanced and the testing circuit board can be maintained at a certain temperature. Therefore, the overheat of the testing circuit board can be prevented, thereby ensuring that the overall testing device can perform high efficiency testing stably.

In some embodiments of the present disclosure, the slide rail component comprises a rail and a plurality of rotating members. The rail extends along the first direction, and the rotating members are rotatably disposed in the rail around a second direction perpendicular to the first direction. The liquid cooling plate leans against these rotating members.

In some embodiments, the slide rail component further comprises a lock component, and the lock component is disposed at one end of the rail to selectively lock the liquid cooling plate.

In some embodiments, the lock component comprises an elastic member, a linkage rod, and an operating member. One of two ends of the linkage rod leans against the other end of the elastic member, and the other end of the linkage rod is connected to the operating member. A portion between the two ends of the linkage rod is pivotally connected to the rail. The one end of the linkage rod is normally locked to the liquid cooling plate. In response to a linear displacement of the operating member, the linkage rod is driven to be pivotally rotated, so that the end of the linkage rod does not block the liquid cooling plate, allowing the liquid cooling plate to selectively slide on the slide rail component.

In some embodiments, the elastic member is a compression spring. The linkage rod is an L-shaped rod. The linkage rod comprises a first body section, a second body section, and a bent portion. The first body section is connected to the operating member. One of two ends of the elastic member leans against the rail, and the other end of the elastic member leans against the second body section of the linkage rod. The bent portion is pivotally connected to the rail.

In some embodiments, the slide rail component comprises a first rail and a second rail. The liquid cooling plate further comprises a first supporting section and a second supporting section. The liquid inlet is at the first supporting section, and the liquid outlet is at the second supporting section. The first supporting section selectively slides on the first rail, and the second supporting section selectively slides on the second rail.

In some embodiments, at least one of the first rail and the second rail comprises a supporting portion. At least one of the first supporting section and the second supporting section further comprise a positioning portion. The supporting portion and the positioning portion are adapted to support a disassembly tool to disassemble the liquid cooling plate.

In some embodiments, the disassembly tool comprises a handle, a fixed arm, a first hook arm, and a second hook arm. The handle is fixed on the fixed arm. One of two ends of the first hook arm and one of two ends of the second hook arm are pivotally connected to the fixed arm, respectively. The other end of the first hook arm is adapted to be engaged with the supporting portion, and the other end of the second hook arm is adapted to be engaged with the positioning portion.

In some embodiments, the first hook arm comprises two hook portions. The two hook portions are at two opposite sides of the first hook arm to be engaged with the supporting portion selectively. The second hook arm comprises a slot and an abutting block. The slot is at one end of the second hook arm away from the fixed arm, and the slot is adapted to be engaged with the positioning portion; the abutting block is between the two ends of the second hook arm, and the abutting block is adapted to push against the liquid cooling plate.

In some embodiments, the liquid cooling testing device further comprises a flow detection module, and the flow detection module is disposed between the liquid-input coupling member and the liquid-output coupling member to detect the flow of the cooling liquid.

In some embodiments, the liquid cooling testing device further comprises a liquid inlet port and a liquid outlet port. The flow detection module comprises a first flowmeter and a second flowmeter. The first flowmeter is disposed between the liquid inlet port and the liquid-input coupling member, and the second flowmeter is disposed between the liquid outlet port and the liquid-output coupling member.

In some embodiments, the liquid cooling testing device further comprises a controller and a power supply. The controller is connected to the first flowmeter, the second flowmeter, and the power supply.

In some embodiments, the liquid cooling testing device further comprises a first blocking member and a second blocking member. The first blocking member is disposed between the liquid-input coupling member and the liquid cooling plate, and the second blocking member is disposed between the liquid-output coupling member and the liquid cooling plate.

In some embodiments, the liquid cooling plate further comprises a first guide hole. The liquid-input coupling member comprises a first guide pin and a first connection portion. The first guide pin and the first connection portion respectively extend from the liquid-input coupling member in the first direction. A length of the first guide pin along the first direction is greater than a length of the first connection portion along the first direction. When the liquid cooling plate is accommodated in the slide rail component, the first guide hole is coupled to the first guide pin, and the liquid inlet is coupled to the first connection portion.

In some embodiments, the liquid cooling plate further comprises a second guide hole. The liquid-output coupling member comprises a second guide pin and a second connection portion. The second guide pin and the second connection portion respectively extend from the liquid-output coupling member in the first direction. A length of the second guide pin along the first direction is greater than a length of the second connection portion along the first direction. When the liquid cooling plate is accommodated in the slide rail component, the second guide hole is coupled to the second guide pin, and the liquid outlet is coupled to the second connection portion.

### BRIEF DESCRIPTION OF THE DRAWINGS

The disclosure will become more fully understood from the detailed description given herein below for illustration only, and thus not limitative of the disclosure, wherein:

FIG. 1 illustrates a schematic perspective view of one embodiment of a liquid cooling testing device.

FIG. 2 illustrates a system block diagram of one embodiment of the liquid cooling testing device.

FIG. 3 illustrates an exploded view of one embodiment of the liquid cooling testing device.

FIG. 4 illustrates a perspective sectional view along the line 4-4 shown in FIG. 1.

FIG. 5 illustrates a plan view of FIG. 4, showing that the lock component is locked to the liquid cooling plate.

FIG. 6 illustrates an enlarged partial view of the circled area 6 shown in FIG. 5.

FIG. 7 illustrates an enlarged partial view of the circled area 7 shown in FIG. 6.

FIG. 8 illustrates a cross-sectional view of one embodiment of the liquid cooling testing device, showing the lock component releases the liquid cooling plate.

FIG. 9 illustrates an enlarged partial view of the circled area 9 shown in FIG. 8.

FIG. 10 illustrates an enlarged partial view of the circled area 10 shown in FIG. 8.

FIG. 11 illustrates a partial perspective sectional view of one embodiment of the liquid cooling testing device, showing that the liquid cooling testing device is used along with a disassembly tool.

FIG. 12 illustrates a first schematic view of the liquid cooling testing device, showing the operation of assembling the liquid cooling plate using the disassembly tool.

FIG. 13 illustrates a second schematic view of the liquid cooling testing device, showing the operation of assembling the liquid cooling plate using the disassembly tool.

FIG. 14 illustrates a first schematic view of the liquid cooling testing device, showing the operation of disassembling the liquid cooling plate using the disassembly tool.

FIG. 15 illustrates a second schematic view of the liquid cooling testing device, showing the operation of disassembling the liquid cooling plate using the disassembly tool.

FIG. 16 illustrates a top schematic view of one embodiment of the liquid cooling testing device.

FIG. 17 illustrates a side schematic view of one embodiment of the liquid cooling testing device.

### DETAILED DESCRIPTION

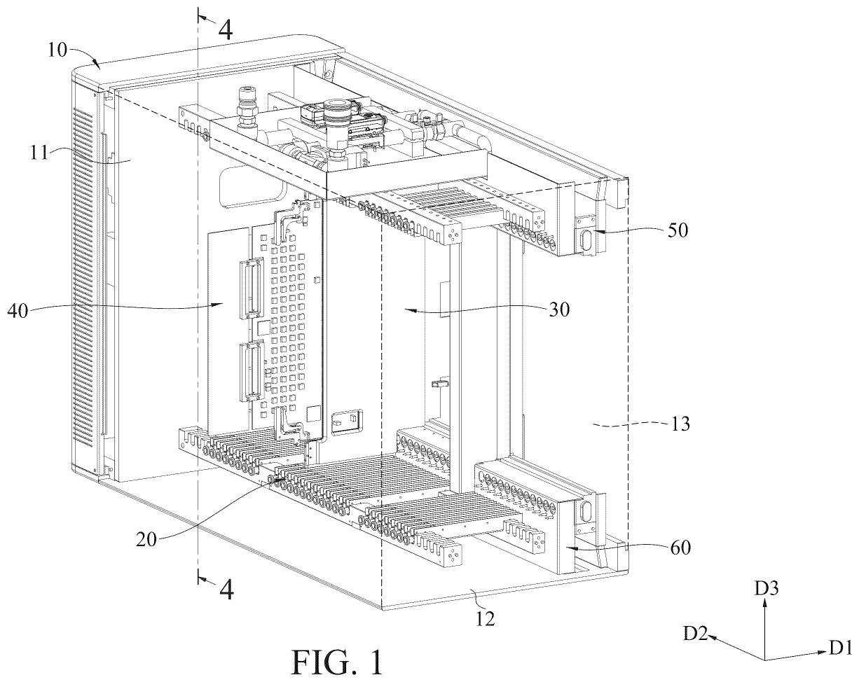

Please refer to FIG. 1 to FIG. 3. One or some embodiments of the instant disclosure provide a liquid cooling testing device that employs a liquid cooling method to cool the testing circuit board. The liquid cooling testing device comprises a body 10, a slide rail component 20, a liquid cooling plate 30, a testing circuit board 40, a liquid-input coupling member 50, a liquid-output coupling member 60, and a cooling liquid supplying module 70.

The slide rail component 20 is disposed on the body 10. The liquid cooling plate 30 is selectively and slidably disposed on the slide rail component 20, and the liquid cooling plate 30 comprises a liquid inlet 35, a channel 36, and a liquid outlet 37 sequentially in communication with each other. The testing circuit board 40 is fixed on the liquid cooling plate 30. The cooling liquid supplying module 70 is in communication with the liquid-input coupling member 50 and the liquid-output coupling member 60. In response to that the liquid cooling plate 30 is slidably disposed on the slide rail component 20, the liquid inlet 35 is coupled to the liquid-input coupling member 50, and the liquid outlet 37 is coupled to the liquid-output coupling member 60. The cooling liquid supplying module 70 supplies a cooling liquid through the liquid-input coupling member 50 to the channel 36 of the liquid cooling plate 30, and the cooling liquid supplying module 70 recycles the cooling liquid from the channel 36 of the liquid cooling plate 30 through the liquid-output coupling member 60.

Thereby, through the circulation of the cooling liquid in the liquid cooling plate 30, the testing circuit board 40 can be cooled, so that the cooling efficiency of the testing circuit board 40 can be enhanced. Therefore, the overheat of the testing circuit board 40 can be prevented, thereby ensuring that the overall testing device can perform high efficiency testing stably.

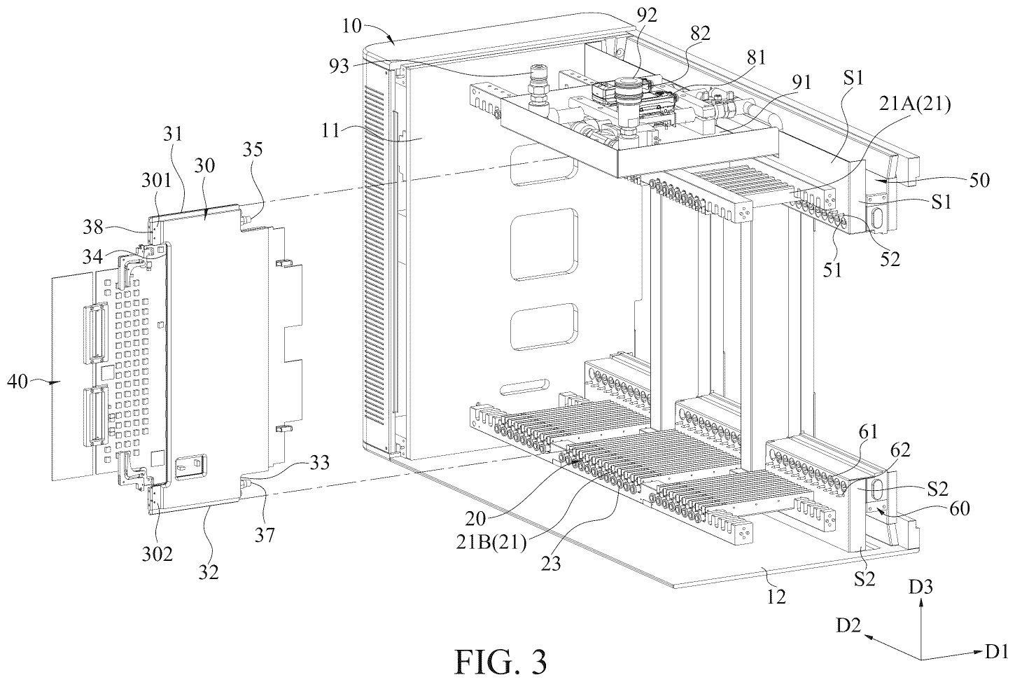

Please refer to FIG. 1 and FIG. 3. The body 10 is configured to load one or multiple circuit boards and serves as a main body for testing operations. In some embodiments of the instant disclosure, the body 10 comprises a panel 11 and a bottom plate 12, and the panel 11 is vertically connected to the bottom plate 12. The space between the panel 11 and the bottom plate 12 is for configuring the testing circuit board 40.

Please refer to FIG. 1 and FIG. 3. The slide rail component 20 is disposed on the body 10 to guide the liquid cooling plate 30 to drive the testing circuit board 40 to be accommodated in the body 10. In some embodiments of the instant disclosure, the slide rail component 20 comprises a rail 21, and a length of the rail 21 extends along a first direction D1. Therefore, the liquid cooling plate 30 is guided to drive the testing circuit board 40 to be moved in the body 10 in the first direction D1 using the rail 21. In these embodiments, the liquid-input coupling member 50, the liquid-output coupling member 60, and an electrical connection port for being electrically connected to the testing circuit board 40 can be positioned at a position of the rail 21 where the liquid cooling plate 30 reaches the end of the rail 21. Thus, when the liquid cooling plate 30 moves to the end of the rail 21 along the rail 21, the testing circuit board 40 can be properly coupled to the liquid-input coupling member 50 and the liquid-output coupling member 60 to form a cooling liquid circulation loop, and the testing circuit board 40 can be further connected to the electrical connection port to establish the electrical connection between the testing circuit board 40 and the liquid cooling testing device.

In some embodiments, the number of the rail 21 of the slide rail component 20 is plural. In these embodiments, a second direction D2 is perpendicular to the first direction D1, and the rails 21 are arranged in parallel and at different positions along the second direction D2. Therefore, a plurality of testing circuit boards 40 can be configured on the liquid cooling testing device at the same time.

Please refer to FIG. 1 and FIG. 3. The liquid cooling plate 30 is provided for the circulation of the cooling liquid to conduct heat dissipation for the testing circuit board 40. In some embodiments, the liquid cooling plate 30 is a plate structure. In these embodiments, the liquid cooling plate 30 has a first side 31, a second side 32, a third side 33, and a fourth side 34. The first side 31 and the second side 32 are parallel and opposite to each other, the third side 33 and the fourth side 34 are parallel and opposite to each other, and the third side 33 and the fourth side 34 are respectively connected between the first side 31 and the second side 32. In this embodiment, the liquid cooling plate 30 is disposed on the rail 21 of the slide rail component 20 with the first side 31and the second side 32 parallel to the first direction D1, while the third side 33 and the fourth side 34 extend along a third direction D3 perpendicular to both the first direction D1 and the second direction D2. The liquid inlet 35 and the liquid outlet 37 are at the third side 33, respectively. Under the configuration that the liquid cooling plate 30 is disposed on the slide rail component 20, the liquid inlet 35 and the liquid outlet 37 are positioned at different positions on the third side 33 of the liquid cooling plate 30 along the third direction D3.

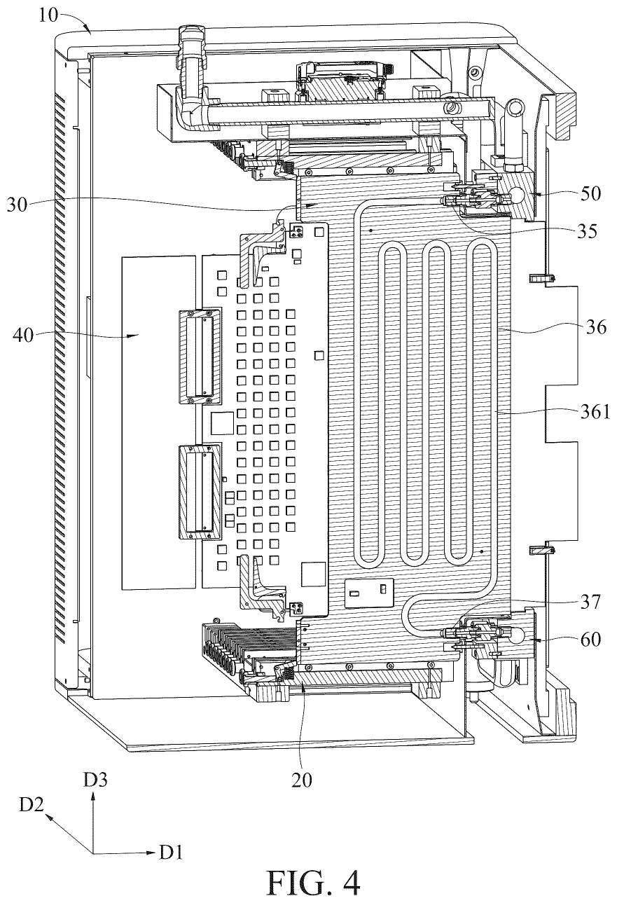

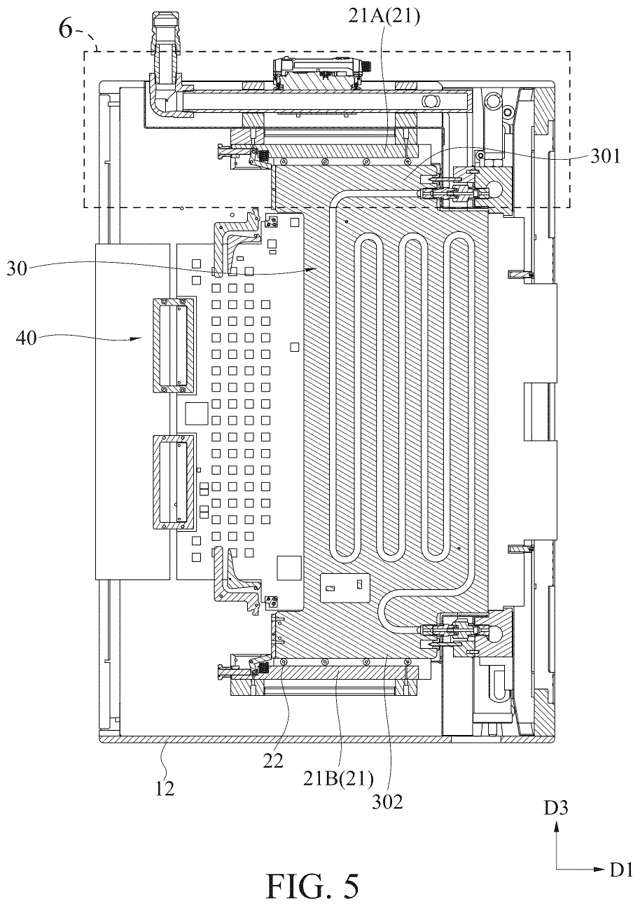

The channel 36 of the liquid cooling plate 30 is meanderingly disposed between the liquid inlet 35 and the liquid outlet 37. Therefore, the heat exchange surface area of the testing circuit board 40 through which the cooling liquid flows can be increased. Please refer to FIG. 4 and FIG. 5. In some embodiments of the instant disclosure, the channel 36 comprises a plurality of extension sections 361 spaced apart from and parallel to each other. Under the configuration that the cooling liquid board 30 is disposed at the slide rail component 20, each of the extension sections 361 extends along the third direction D3, but the instant disclosure is not limited thereto. In some embodiments where the channel 36 comprises the extension sections 361, the extension sections 361 of the channel 36 may also extend along the first direction D1 and parallel to each other. It is worth mentioning that, according to the position of the heat sources configured on the testing circuit board 40, the extension sections 361 of the channel 36 in the liquid cooling plate 30 can be adjusted in terms of density, extension direction, position, or pattern to correspond to the heat sources on the testing circuit board 40, thereby providing optimal cooling efficiency.

Please refer to FIG. 1 and FIG. 3. The testing circuit board 40 is adapted to perform various computations during testing operations. The testing circuit board 40 is substantially of a plate structure, and the testing circuit board 40 is attached and fixed to one side of the liquid cooling plate 30 with the maximum contact area. In some embodiments of the instant disclosure, the testing circuit board 40 can be fixed to the liquid cooling plate 30 by locking or snapping mechanisms, but the instant disclosure is not limited thereto.

The liquid-input coupling member 50 is configured to be coupled to the liquid inlet 35 of the liquid cooling plate 30 for supplying the cooling liquid to the liquid cooling plate 30. In some embodiments of the instant disclosure, the number of the liquid-input coupling member 50 may be singular or multiple. In these embodiments of the instant disclosure, the number of the liquid-input coupling member 50 may correspond to the number of the liquid cooling plate 30, and the liquid inlet 35 of each of the liquid cooling plates 30 is coupled to a corresponding one of the liquid-input coupling members 50, but the instant disclosure is not limited thereto. As shown in FIG. 1 and FIG. 3, the number of the liquid-input coupling member 50 may also be singular. In this embodiment, the liquid-input coupling member 50 has a plurality of first connection portions 51, and each of the first connection portions 51 can be coupled to the liquid inlet 35 of a corresponding one of the liquid cooling plates 30. Therefore, the first connection portions 51 can be congregated to the single liquid-input coupling member 50, thereby facilitating the coupling between the cooling liquid supplying module 70 and the liquid-input coupling member 50.

Please refer to FIG. 1. In some embodiments where the number of the liquid-input coupling member 50 is singular, the liquid-input coupling member 50 extends in length along the second direction D2. In these embodiments of the instant disclosure, the body 10 further comprises a back plate 13. The back plate 13 is connected to the bottom plate 12 and parallel to the panel 11. In this embodiment, both ends of the liquid-input coupling member 50 are fixedly connected between the panel 11 and the back plate 13. Therefore, the liquid-input coupling member 50, the panel 11, and the back plate 13 form a stable structural configuration.

Please refer to FIG. 1 and FIG. 3 to FIG. 5, the liquid-output coupling member 60 is configured to be coupled to the liquid outlet 37 of the liquid cooling plate 30 to recover the cooling liquid flowing through the liquid cooling plate 30. In some embodiments of the instant disclosure, the number of the liquid-output coupling member 60 may correspond to the number of the liquid cooling plate 30, and the liquid outlet 37 of each of the liquid cooling plates 30 is coupled to a corresponding one of the liquid-output coupling members 60, but the instant disclosure is not limited thereto. As shown in FIG. 1 and FIG. 3, the number of the liquid-output coupling member 60 may also be singular. In this embodiment, the liquid-output coupling member 60 has a plurality of second connection portions 61, and each of the second connection portions 61 can be coupled to the liquid outlet 37 of a corresponding one of the liquid cooling plates 30. Therefore, the second connection portions 61 can be congregated to the single liquid-output coupling member 60, thereby facilitating the coupling between the cooling liquid supplying module 70 and the liquid-output coupling member 60.

Please refer to FIG. 1 and FIG. 3. In some embodiments where the number of the liquid-output coupling member 60 is singular, the liquid-output coupling member 60 extends in length along the second direction D2. In these embodiments of the instant disclosure, both ends of the liquid-output coupling member 60 are fixedly connected between the panel 11 and the back plate 13 of the body 10. In this embodiment, the liquid-output coupling member 60 is parallel to the liquid-input coupling member 50 and is disposed at different positions along the third direction D3. Specifically, in this embodiment, the position of the second connection portion 61 of the liquid-output coupling member 60 along the third direction D3 is aligned with the position of the liquid outlet 37 of the liquid cooling plate 30 along the third direction D3. Likewise, the position of the first connection portion 51 of the liquid-input coupling member 50 in the third direction D3 is aligned with the position of the liquid inlet 35 of the liquid cooling plate 30 in the third direction D3. As a result, the liquid cooling plate 30 only needs to be linearly moved to the end of the rail 21 along the slide rail component 20, the liquid inlet 35 of the liquid cooling plate 30 can be correspondingly coupled to the first connection portion 51 of the liquid-input coupling member 50, and the liquid outlet 37 can then be correspondingly coupled to the second connection portion 61 of the liquid-output coupling member 60, thereby the assembling of the testing circuit board 40 can be completed at the same time.

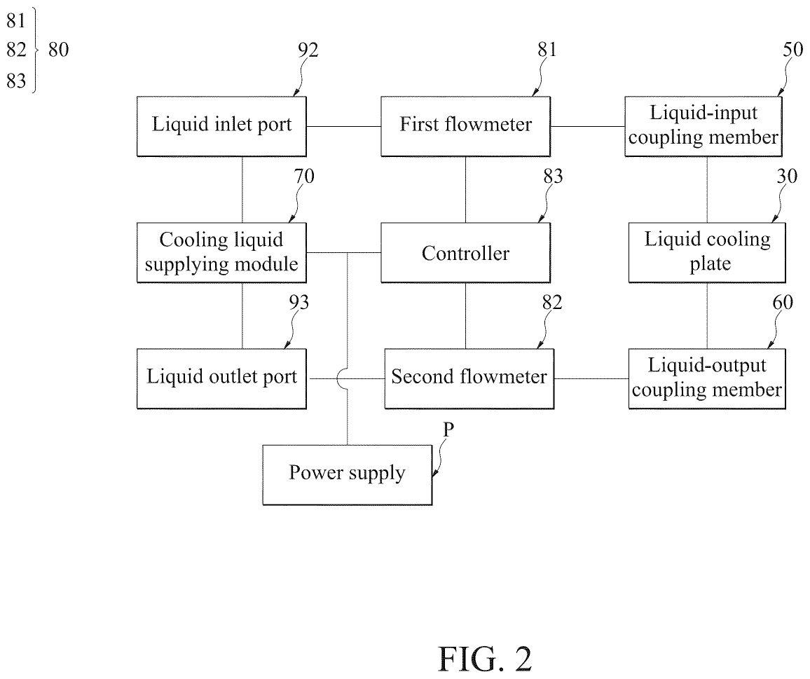

Please refer to FIG. 2. The cooling liquid supplying module 70 is configured to supply the cooling liquid circulated in the liquid cooling plate 30. In some embodiments of the instant disclosure, the cooling liquid supplying module 70 is configured as cooling distribution units (CDU) or a chiller.

Based on the above, upon the assembling of the testing circuit board 40, the testing circuit board 40 and the liquid cooling plate 30 are slidably disposed on the slide rail component 20. When the liquid cooling plate 30 moves to the stroke endpoint of the slide rail component 20, the liquid inlet 35 of the liquid cooling plate 30 is coupled to the first connection portion 51 of the liquid-input coupling member 50, and the liquid outlet 37 is coupled to the second connection portion 61 of the liquid-output coupling member 60. The cooling liquid supplying module 70 supplies the cooling liquid to the channel 36 of the liquid cooling plate 30 through the liquid-input coupling member 50. The cooling liquid flows through the channel 36 to conduct heat dissipation for the testing circuit board 40 to cool the testing circuit board 40. The cooling liquid which flew through the channel 36 is then recovered from the liquid cooling plate 30 through the liquid-output coupling member 60. Accordingly, the cooling liquid can be continuously circulated within the liquid cooling plate 30, thereby providing continuous heat dissipation and cooling for the testing circuit board 40, and thus enhancing the cooling efficiency for the testing circuit board 40.

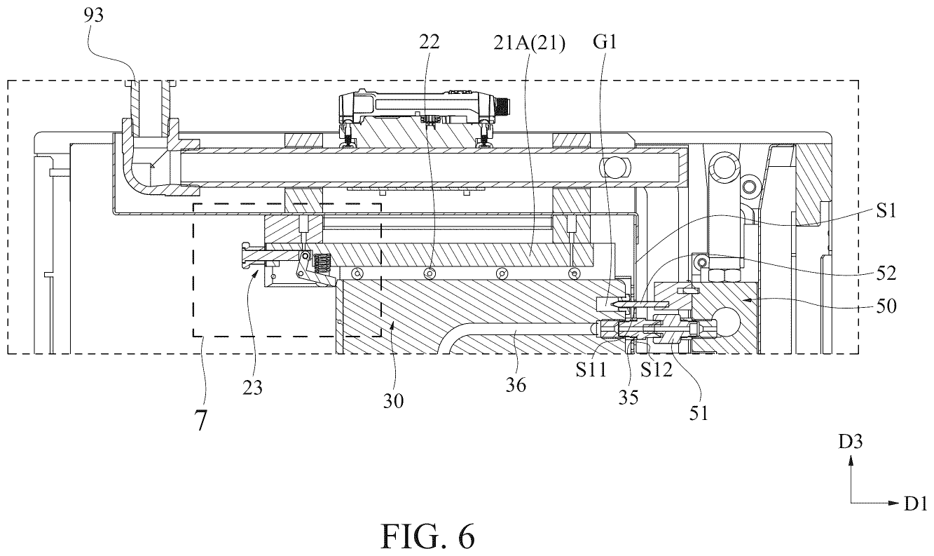

Please refer to FIG. 4 and FIG. 6. In some embodiments of the instant disclosure, the slide rail component 20 further comprises a plurality of rotating members 22. The rotating member 22 has a circular outer peripheral surface, and the rotating member 22 is rotatably disposed inside the rail 21 around the second direction D2. Therefore, when the liquid cooling plate 30 is disposed on the rail 21, the liquid cooling plate 30 leans against the outer peripheral surface of each of the rotating members 22. The circular outer peripheral surface of the rotating member 22 can decrease the contact resistance between the liquid cooling plate 30 and the rotating member 22, and the rotating member 22 can be freely rotated, making the liquid cooling plate 30 smoothly and linearly be moved in the rail 21 along the first direction D1, thus achieving labor-saving effect.

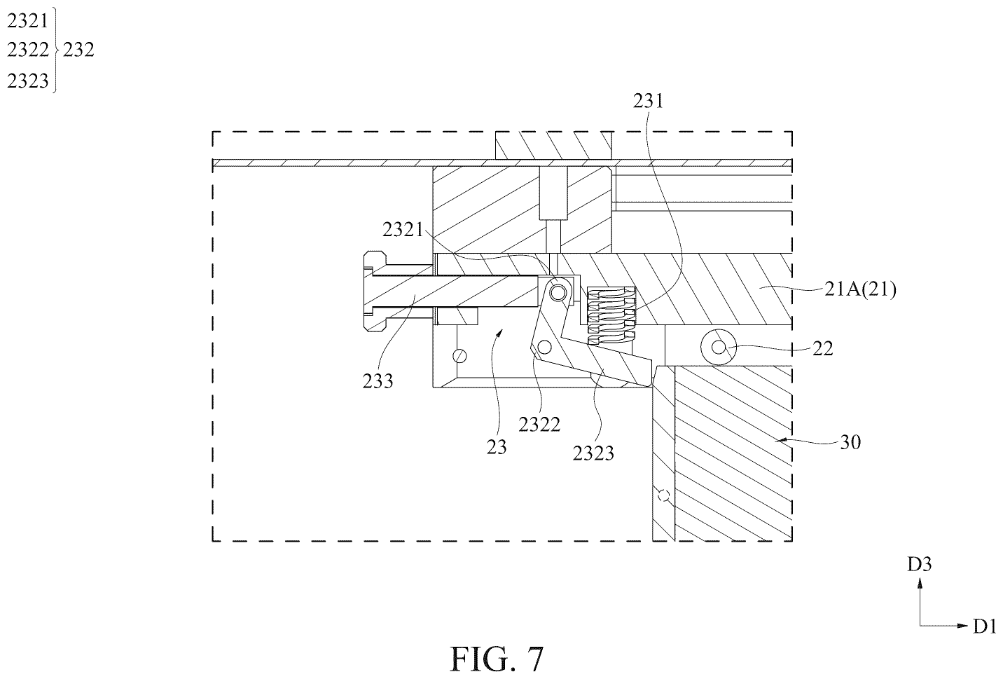

Please refer to FIG. 6 and FIG. 7. In some embodiments of the instant disclosure, the slide rail component 20 further comprises a lock component 23, and the lock component 23 is fixed on one end of the rail 21 away from the liquid-input coupling member 50 or away from the liquid-output coupling member 60, so that the lock component 23 is selectively locked to the liquid cooling plate 30 to prevent the detachment of the testing circuit board 40 and the liquid cooling plate 30. In these embodiments of the instant disclosure, the lock component 23 comprises an elastic member 231, a linkage rod 232, and an operating member 233. One of two ends of the linkage rod 232 leans against the elastic member 231 and is normally locked to the liquid cooling plate 30, the other end of the linkage rod 232 is connected to the operating member 233, and a portion between the two ends of the linkage rod 232 is pivotally connected to the rail 21. In these embodiments of the instant disclosure, in response to a linear displacement of the operating member 233, the lock component 23 drives the linkage rod 232 to be pivotally rotated, so that the end of the linkage rod 232 does not block the liquid cooling plate 30, allowing the liquid cooling plate 30 to selectively slide on the slide rail component 20.

Please refer to FIG. 7. In some embodiments of the instant disclosure, the elastic member 231 is a compression spring that normally extends and stores an elastic force when being compressed. In these embodiments of the instant disclosure, one of two ends of the elastic member 231 is fixed on the rail 21, and the other end of the elastic member 231 leans against the linkage rod 232.

Please refer to FIG. 7. In some embodiments of the instant disclosure, the linkage rod 232 is a rod which has a bent portion 2322. In these embodiments of the instant disclosure, the linkage rod 232 comprises a first body section 2321, the bent portion 2322, and a second body section 2323. Here, an extension line of the first body section 2321 and an extension line of the second body section 2323 are connected to the bent portion 2322. The bent portion 2322 forms an angle that is neither 0 degree nor 180 degrees. As shown in the embodiment of FIG. 7, the bent portion 2322 forms an angle that is 90 degrees. In this embodiment, the linkage rod 232 is an L-shaped rod.

Please refer to FIG. 7. In these embodiments of the instant disclosure, the second body section 2323 of the linkage rod 232 leans against the other end of the elastic member 231. The first body section 2321 is connected to the operating member 233. The operating member 233 partially protrudes from the rail 21 for the user to operate, and the bent portion 2322 is pivotally connected to the rail 21.

The following paragraphs will explain the operation of the lock component 23. In some embodiments where the elastic member 231 is a compression spring, the elastic member 231 normally expands to push against the second body section 2323 of the linkage rod 232, and the first body section 2321 of the elastic member 231 leans against the rail 21 to form a stable locked state (as shown in the state of FIG. 7). Under this state, the second body section 2323 of the linkage rod 232 along the third direction D3 overlaps the liquid cooling plate 30. Thus, the lock component 23 is blocked at one end of the rail 21, thereby restricting the displacement of the liquid cooling plate 30 on the rail 21, and thus the lock component forming a locked state.

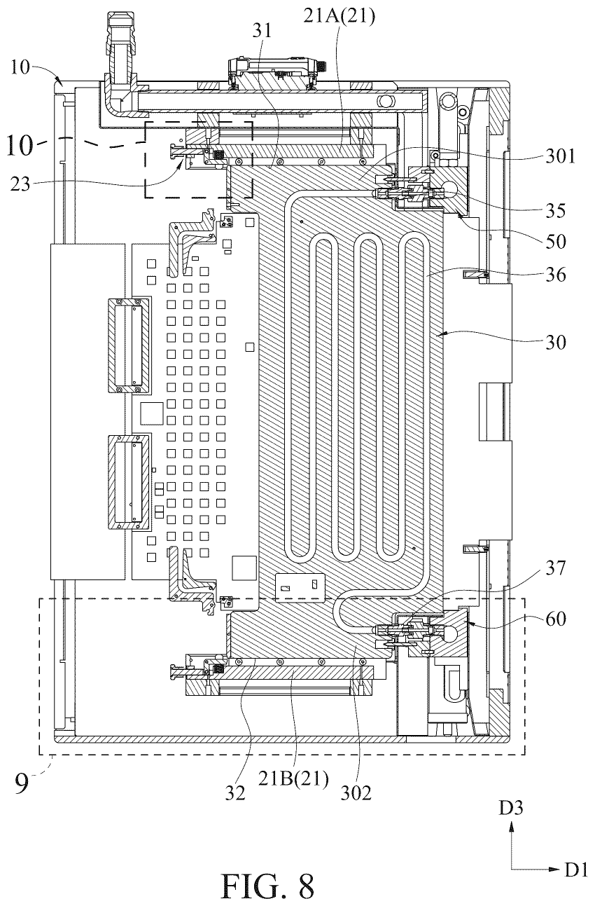

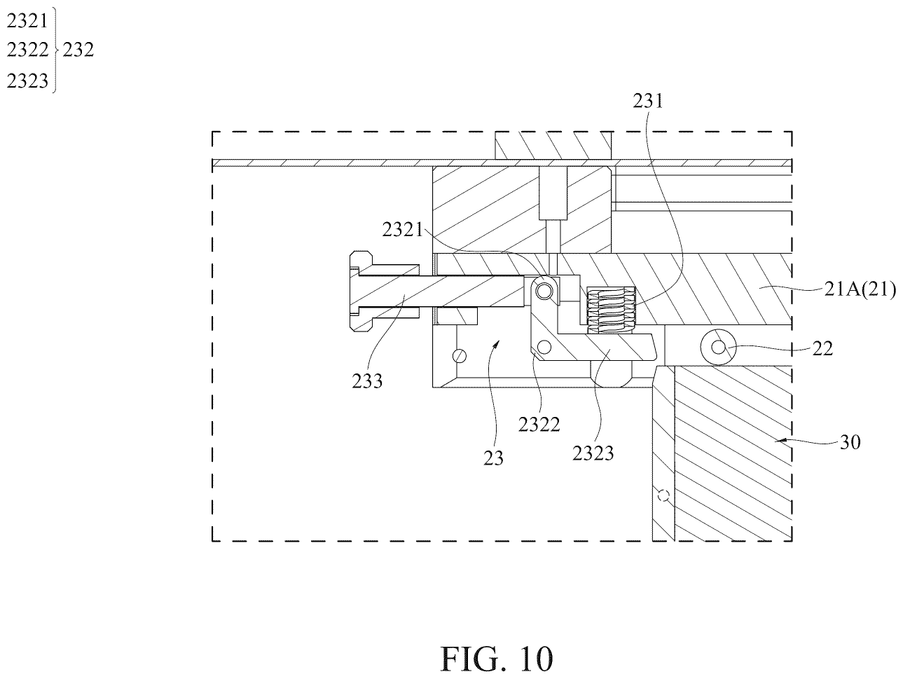

When the locked state of the lock component 23 is to be released, the operating member 233 is pulled along the first direction D1, and the operating member 233 drives the first body section 2321 of the linkage rod 232, so that the linkage rod 232 is pivotally rotated by taking the bent portion 2322 as a pivot center. When the linkage rod 232 is pivotally rotated, the second body section 2323 of the linkage rod 232 compresses the elastic member 231 and moves toward the elastic member 231. In this way, the second body section 2323 of the linkage rod 232 can also gradually move away from the liquid cooling plate 30 along the third direction D3, and it changes into a state where the position of the linkage rod 232 along the third direction D3 no longer overlaps the liquid cooling plate 30 (as shown in FIG. 8 and FIG. 10). Therefore, the rail 21 is no longer blocked by the lock component 23, and thus the lock component 23 forming a released state. Therefore, the liquid cooling plate 30 can freely and linearly move on the rail 21. Furthermore, when the liquid cooling plate 30 has been disassembled or assembled, an operator can just release the force applied to the operating member 233, so that the compression force applied to the elastic member 231 will then disappear. Therefore, the elastic member 231 releases the elastic force to return to an expanded state, thereby automatically pushing against the linkage rod 232 back to the locked state.

Please refer to FIG. 8. In some embodiments of the instant disclosure, the number of the rail 21 of the slide rail component 20 is two; in this embodiment, the two rails 21 are respectively referred to as a first rail 21A and a second rail 21B for clarity in the explanation. In these embodiments of the instant disclosure, the liquid cooling plate 30 along the third direction D3 respectively includes a first supporting section 301 and a second supporting section 302. The first supporting section 301 extends to the first side 31, and the second supporting section 302 extends to the second side 32. The liquid inlet 35 is at the first supporting section 301, and the liquid outlet 37 is at the second supporting section 302. The first supporting section 301 selectively slides on the first rail 21A, and the second supporting section 302 selectively slides on the second rail 21B. Hereby, both sides of the liquid cooling plate 30 along the third direction D3 can be accommodated in the slide rail component 20, ensuring the stability of the liquid cooling plate 30 and the testing circuit board 40 on the liquid cooling plate 30.

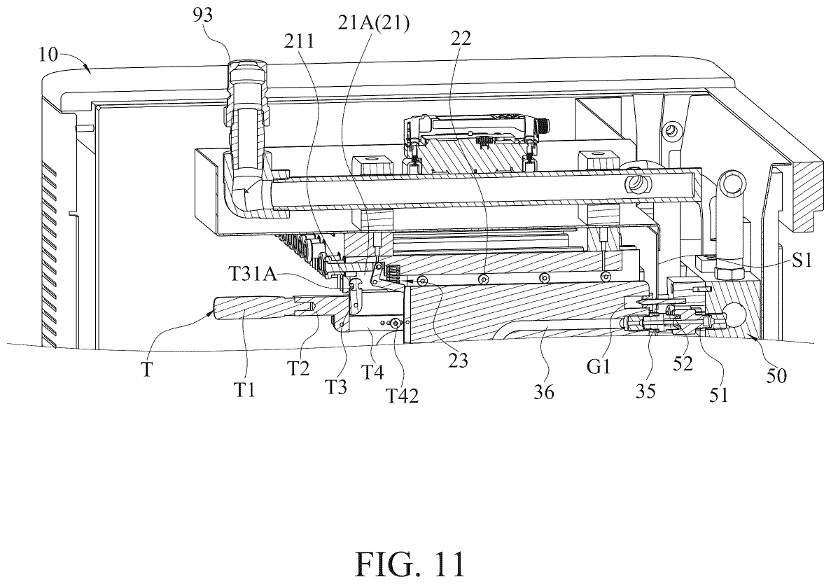

Please refer to FIG. 11 to FIG. 15. In some embodiments of the instant disclosure, at least one of the rails 21 comprises a supporting portion 211. One of the first supporting section 301 and the second supporting section 302 comprises a positioning portion 38. The supporting portion 211 of the rail 21 and the positioning portion 38 of the liquid cooling plate 30 are adapted to support a disassembly tool T to disassemble the liquid cooling plate 30.

In some embodiments of the instant disclosure, the disassembly tool T comprises a handle T1, a fixed arm T2, a first hook arm T3, and a second hook arm T4. The handle T1 is fixed on the fixed arm T2, and one of two ends of the first hook arm T3 and one of two ends of the second hook arm T4 are pivotally connected to the fixed arm T2, respectively. The other end of the first hook arm T3 is adapted to be engaged with the supporting portion 211 of the rail 21, and the other end of the second hook arm T4 is adapted to be engaged with the positioning portion 38 of the liquid cooling plate 30. Hereby, through the supporting of the supporting portion 211 and the positioning portion 38, the operator can use the disassembly tool T to apply force to disassemble or assemble the liquid cooling plate 30 using the lever principle, making the assembling/disassembling process of the liquid cooling plate 30 more convenient.

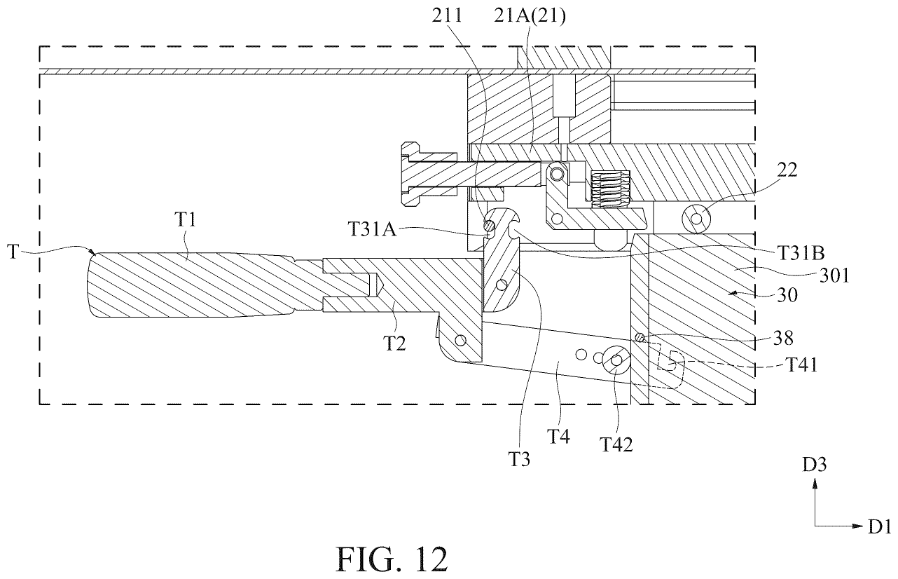

Please refer to FIG. 11 and FIG. 12. In some embodiments of the instant disclosure, the first hook arm T3 comprises a first hook portion T31A and a second hook portion T31B. The first hook portion T31A and the second hook portion T31B are at two opposite sides of the end of the first hook arm T3 that is away from the fixed arm T2, and the first hook portion T31A and the second hook portion T31B are selectively engaged with the supporting portion 211 of the rail 21. An opening of the first hook portion T31A faces the handle T1, while an opening of the second hook portion T31B faces away from the handle T1. The second hook arm T4 has a slot T41 and an abutting block T42. The slot T41 is at one end of the second hook arm T4 away from the fixed arm T2, and the slot T41 is adapted to be engaged with the positioning portion 38 of the liquid cooling plate 30; the abutting block T42 is disposed between the two ends of the second hook arm T4, and the abutting block T42 is adapted to push against the liquid cooling plate 30.

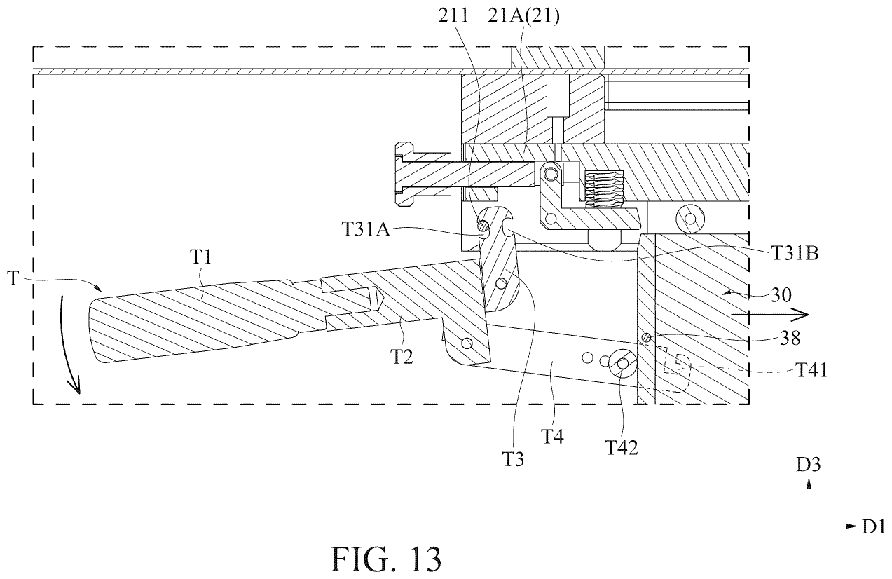

The following paragraph will illustrate the operation of the disassembly tool T. When the disassembly tool T is used to assemble the testing circuit board 40, as shown in FIG. 12 and FIG. 13, first, the lock component 23 is operated to be the released state; the operation of the lock component 23 has been previously described and will not be repeated here. When the lock component 23 is into the released state, the liquid cooling plate 30 and the testing circuit board 40 are placed in the rail 21. Under this state, the first supporting section 301 or the second supporting section 302 of the liquid cooling plate 30 leans against the rotating member 22. Next, the first hook portion T31A of the first hook arm T3 of the disassembly tool T is used to be engaged with the supporting portion 211 of the rail 21, and the abutting block T42 of the second hook arm T4 faces the liquid cooling plate 30. Under this state, the operator can grip the handle T1 of the disassembly tool T to apply force to the liquid cooling plate 30 by taking the supporting portion 211 as a fulcrum using the lever principle.

From the perspective shown in FIG. 13, by applying a downward force on the handle T1, the abutting block T42 of the second hook arm T4 can push against the liquid cooling plate 30 to apply the force to the liquid cooling plate 30. Therefore, the testing circuit board 40 and the liquid cooling plate 30 can be together pushed in the rail 21 to achieve the assembling. After the testing circuit board 40 is assembled with the liquid cooling plate 30, the position of the testing circuit board 40 along the first direction D1 becomes misaligned with the lock component 23, allowing the lock component 23 to move resiliently and automatically return to the locked state (as shown in FIG. 5 and FIG. 6) to prevent the detachment of the testing circuit board 40 and the liquid cooling board 30.

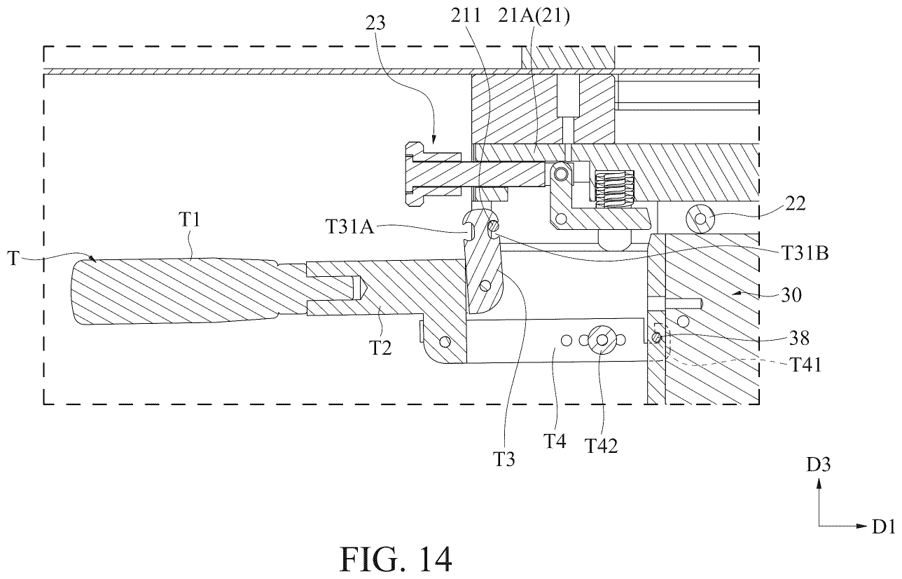

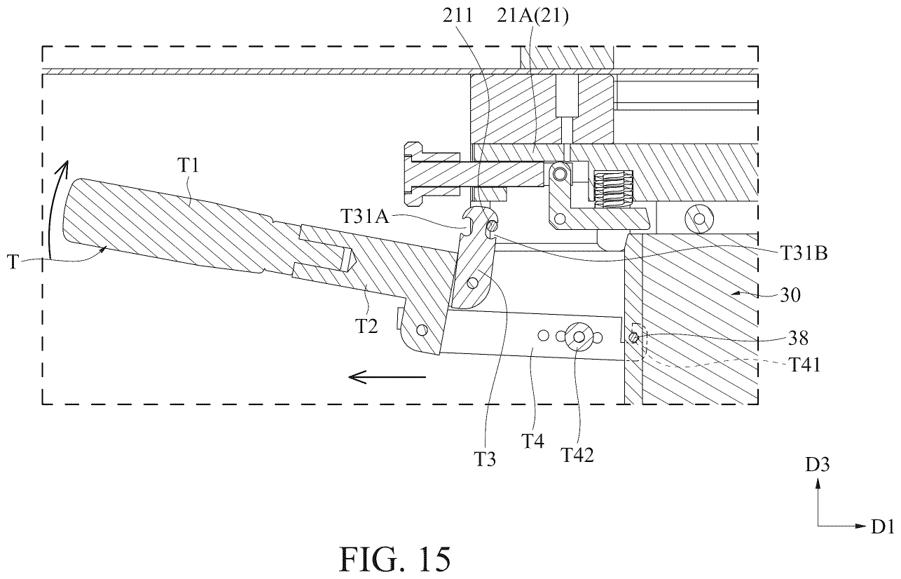

When the testing circuit board 40 is to be disassembled, as shown in FIG. 14 and FIG. 15, first, similarly, the lock component 23 is operated to be the released state; the operation of the lock component 23 has been previously described and will not be repeated here. When the lock component 23 is into the released state, the second hook portion T31B of the first hook arm T3 of the disassembly tool T is engaged with the supporting portion 211 of the rail 21, and the slot T41 of the second hook arm T4 is inserted into the positioning portion 38 of the liquid cooling plate 30. Under the state, the operator can grip the handle T1 of the disassembly tool T to apply force to the liquid cooling plate 30 by taking the supporting portion 211 as a fulcrum using the lever principle to detach the liquid cooling plate 30 and the testing circuit board 40 from the slid rail component 20.

From the perspective shown in FIG. 14 and FIG. 15, by applying an upward force on the handle T1, the slot T41 of the second hook arm T4 can pull the positioning portion 38 of the liquid cooling plate 30 outward from the rail 21. Hereby, with the assistance of the disassembly tool T, the operator can use the lever principle to effortlessly disassemble the testing circuit board 40. Thus, the assembling and disassembling of testing circuit boards 40 with larger sizes can be achieved conveniently.

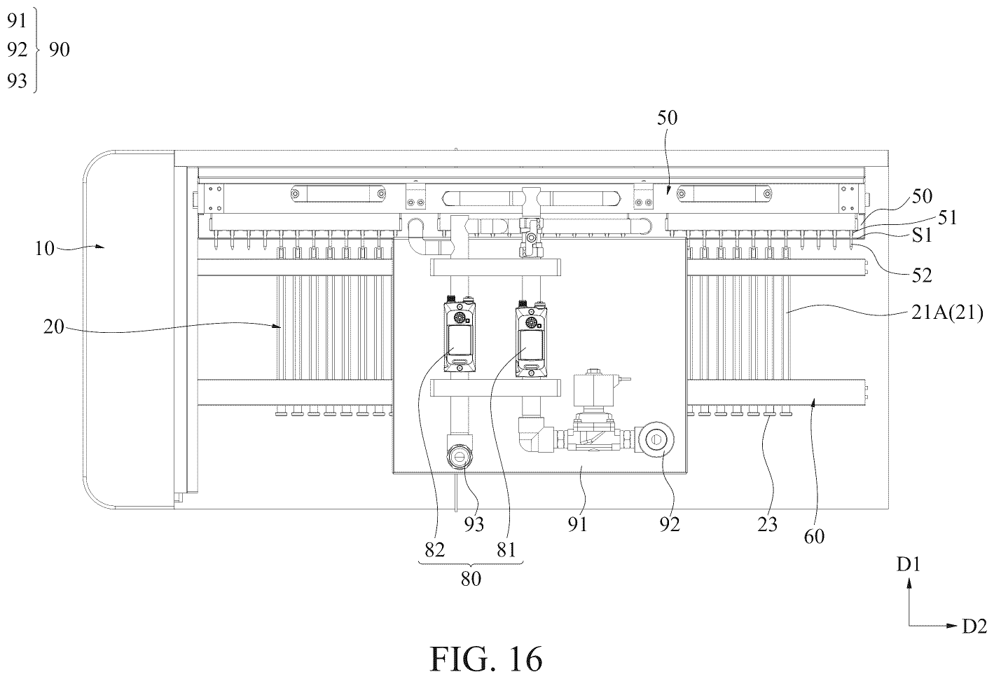

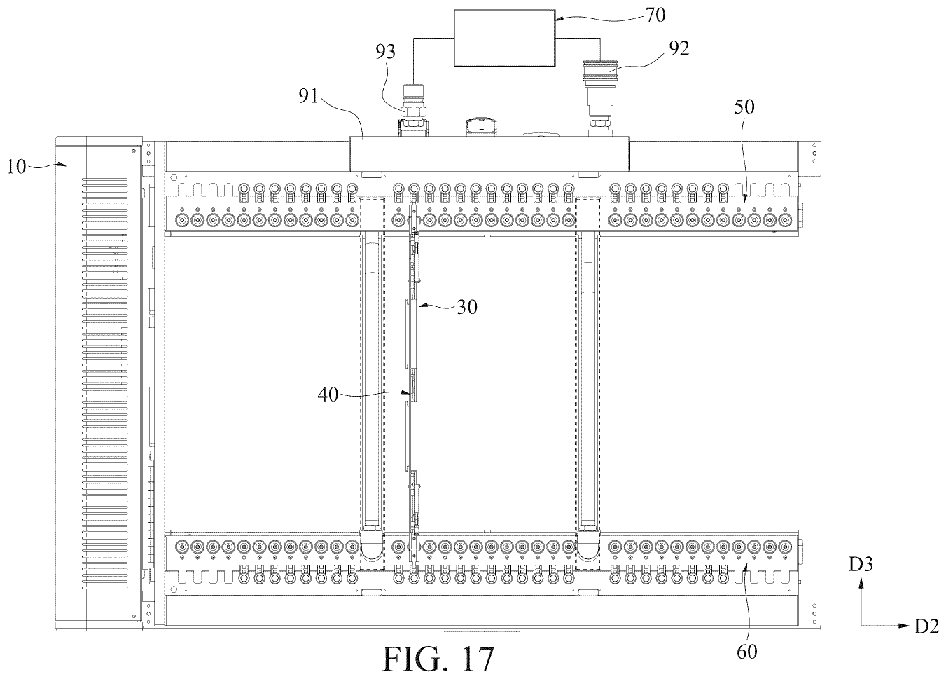

Please refer to FIG. 2, FIG. 16, and FIG. 17. In some embodiments of the instant disclosure, the liquid cooling testing device further comprises a flow detection module 80. The flow detection module 80 is disposed between the liquid-input coupling member 50 and the liquid-output coupling member 60 to detect the flow of the cooling liquid. Therefore, through the configuration of the flow detection module 80, when the flow of the cooling liquid is detected to be abnormal, alerts or corresponding treatments can be timely conducted.

Please refer to FIG. 2, FIG. 16, and FIG. 17. In some embodiments where the liquid cooling testing device includes the flow detection module 80, the flow detection module 80 comprises a first flowmeter 81 and a second flowmeter 82. The first flowmeter 81 is configured to detect the flow of the cooling liquid inputted to the liquid cooling plate 30, and the second flowmeter 82 is configured to detect the flow of the cooling liquid outputted from the liquid cooling plate 30. Thus, when a difference is between the input flow and the output flow of the cooling liquid, the abnormalities can be detected and timely addressed.

Please refer to FIG. 2, FIG. 16, and FIG. 17. In some embodiments of the instant disclosure, the liquid cooling testing device further comprises an integration module 90. The integration module 90 comprises a platform 91, a liquid inlet port 92, and a liquid outlet port 93. The platform 91 and the bottom plane 12 are disposed on the body 10 in parallel. In this embodiment, along the third direction D3, the liquid cooling plate 30 is disposed between the platform 91 and the bottom plate 12. In these embodiments of the instant disclosure, the liquid inlet port 92 and the liquid outlet port 93 are on a platform 91 respectively and the liquid inlet port 92 and the liquid outlet port 93 are configured to be connected to the cooling liquid supplying module 70. Furthermore, the liquid inlet port 92 and the liquid outlet port 93 are connected to the liquid-input coupling member 50 and the liquid-output coupling member 60 through pipe lines. In this embodiment, the first flowmeter 81 is between the liquid inlet port 92 and the liquid-input coupling member 50, and the second flowmeter 82 is disposed between the liquid outlet port 93 and the liquid-output coupling member 60. Hereby, the first flowmeter 81 and the second flowmeter 82 can immediately detect the volume of the cooling liquid inputted from the liquid inlet port 92 into the liquid cooling plate 30 and the volume of the cooling liquid outputted from the liquid cooling plate 30.

Please refer to FIG. 2. In some embodiments of the instant disclosure, the liquid cooling testing device further comprises a power supply P, and the flow detection module 80 further comprises a controller 83. The power supply P is electrically connected to each of the testing circuit boards 40. The controller 83 is connected to the first flowmeter 81, the second flowmeter 82, the power supply P, and the cooling liquid supplying module 70. In these embodiments of the instant disclosure, the controller 83 can control the power supply P to be turned on or off based on the detected outcomes of the first flowmeter 81 and the second flowmeter 82.

Specifically, in some embodiments, when the controller 83 receives that the input volume of the cooling liquid detected by the first flowmeter 81 is different from the output volume of the cooling liquid detected by the second flowmeter 82 (or when the difference between the input volume and the output volume exceeds a preset value), the controller 83 determines that an abnormal loss (such as leakage) may occur to the circulation loop of the cooling liquid, and the controller 83 turns off the power supply P to stop the testing procedure based on the detected outcome or the controller 83 turns off the cooling liquid supplying module 70 to stop circulation of the cooling liquid.

Please refer to FIG. 1 and FIG. 3. In some embodiments of the instant disclosure, the liquid cooling testing device further comprises a first blocking member S1 and a second blocking member S2. The first blocking member S1 is disposed between the liquid-input coupling member 50 and the liquid cooling plate 30, and the second blocking member S2 is disposed between the liquid-output coupling member 60 and the liquid cooling plate 30. Hereby, the first blocking member S1 can be blocked between the liquid-input coupling member 50 and the liquid cooling plate 30, and the second blocking member S2 can be blocked between the liquid-output coupling member 60 and the liquid cooling plate 30. Therefore, the liquid-input coupling member 50 or the liquid-output coupling member 60 can be prevented from accidentally spraying the cooling liquid to make the damage of the testing circuit board 40.

Please refer to FIG. 4 to FIG. 6. In some embodiments of the instant disclosure, the liquid cooling plate 30 further comprises a first guide hole G1, and the liquid-input coupling member 50 further comprises a first guide pin 52. In these embodiments of the instant disclosure, the appearance of the first guide pin 52 and the appearance of the first connection portion 51 are respectively cylinder structures extending from the liquid-input coupling member 50 along the first direction D1, and a length of the first guide pin 52 along the first direction D1 is greater than a length of the first connection portion 51 along the first direction D1. In this embodiment, when the liquid cooling plate 30 is accommodated in the slide rail component 20, because the length of the first guide pin 52 along the first direction D1 is greater than the length of the first connection portion 51 along the first direction D1, the first guide hole G1 of the liquid cooling plate 30 will be first coupled to the first guide pin 52. After the first guide hole G1 is coupled to the first guide pin 52, the liquid inlet 35 is then coupled to the first connection portion 51. Hereby, the cooperation between the first guide hole G1 and the first guide pin 52 can guide the liquid cooling plate 30 to be correctly assembled on the liquid-input coupling member 50, thereby increasing the convenience of the assembling.

Please refer to FIG. 6. In some embodiments of the liquid cooling testing device comprising a first blocking member S1, the first blocking member S1 comprises a plurality of pin through holes S11 and a plurality of first through openings S12. In these embodiments of these instant disclosure, each of the first guide pins 52 of the liquid-input coupling member 50 passes through a corresponding one of the pin through holes S11. A position of each of the first connection portions 51 corresponds to a position of the corresponding one of the first through opening S12, and each of the first connection portions 51 is between the corresponding one of the first through openings S12 and the liquid-input coupling member 50. Hereby, it is ensured that the liquid cooling plate 30 can be first guided by the first guide pin 52 so as to be connected to the first connection portion 51 correctly.

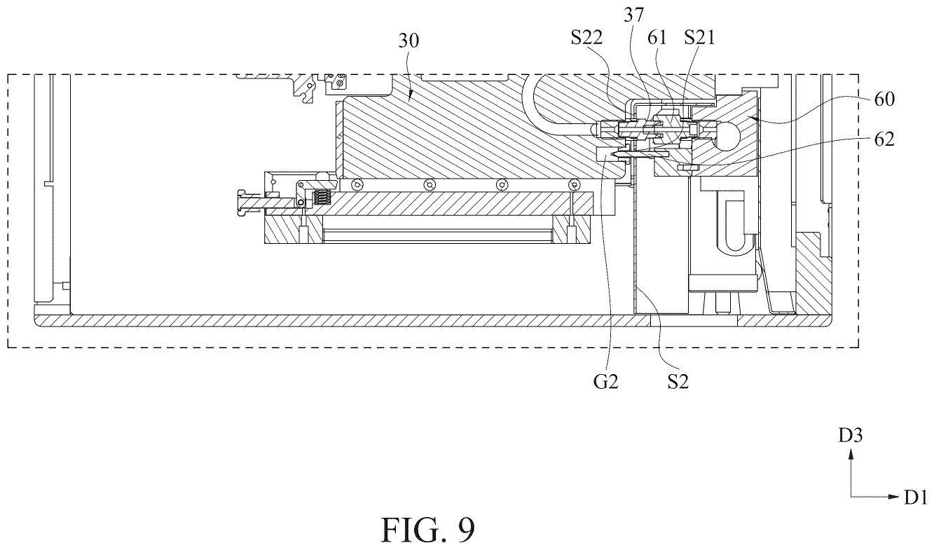

Please refer to FIG. 8 and FIG. 9. In some embodiments of the instant disclosure, the liquid cooling plate 30 further comprises a second guide hole G2, and the liquid-output coupling member 60 further comprises a second guide pin 62. The appearance of the second guide pin 62 and the appearance of the second connection portion 61 are respectively cylinder structures extending from the liquid-output coupling member 60 along the first direction D1, and a length of the second guide pin 62 along the first direction D1 is greater than a length of the second connection portion 61 along the first direction D1. When the liquid cooling plate 30 is accommodated in the slide rail component 20, because the length of the second guide pin 62 along the first direction D1 is greater than the length of the second connection portion 61 along the first direction D1, the second guide hole G2 of the liquid cooling plate 30 will be first coupled to the second guide pin 62. After the second guide hole G2 is coupled to the second guide pin 62, the liquid outlet 37 is then coupled to the second connection portion 61. Hereby, the cooperation between the second guide hole G2 and the second guide pin 62 can guide the liquid cooling plate 30 to be correctly assembled on the liquid-output coupling member 60, thereby increasing the convenience of the assembling.

Please refer to FIG. 9. In some embodiments of the liquid cooling testing device comprises a second blocking member S2, the second blocking member S2 comprises a plurality of pin through holes S21 and a plurality of second through openings S22. In these embodiments of the instant disclosure, each of the second guide pins 62 of the liquid-output coupling member 60 passes through a corresponding one of the pin through holes S21. A position of each of the second connection portions 61 corresponds to a position of a corresponding one of the second through openings S22, and each of the second connection portions 61 is between the corresponding one of the second through openings S22 and the liquid-output coupling member 60. Hereby, it is ensured that the liquid cooling plate 30 can be first guided by the second guide pin 62 so as to be connected to the second connection portion 61 correctly.

What is claimed is:

1. A liquid cooling testing device comprising:
a body;
a slide rail component disposed on the body;
a liquid cooling plate selectively and slidably disposed on the slide rail component, wherein the liquid cooling plate comprises a liquid inlet, a channel, and a liquid outlet sequentially in communication with each other;
a testing circuit board fixed on the liquid cooling plate;
a liquid-input coupling member;
a liquid-output coupling member; and
a cooling liquid supplying module in communication with the liquid-input coupling member and the liquid-output coupling member;
wherein in response to that the liquid cooling plate is slidably disposed on the slide rail component, the liquid inlet is coupled to the liquid-input coupling member, and the liquid outlet is coupled to the liquid-output coupling member; the cooling liquid supplying module supplies a cooling liquid to the channel of the liquid cooling plate through the liquid-input coupling member and recycles the cooling liquid from the channel of the liquid cooling plate through the liquid-output coupling member.

2. The liquid cooling testing device according to claim 1, wherein the slide rail component comprises a rail and a plurality of rotating members, the rail extends along the first direction, the rotating members are rotatably disposed in the rail around a second direction perpendicular to the first direction, and the liquid cooling plate leans against the rotating members.

3. The liquid cooling testing device according to claim 2, wherein the slide rail component further comprises a lock component, and the lock component is disposed at one end of the rail to selectively lock the liquid cooling plate.

4. The liquid cooling testing device according to claim 3, wherein the lock component comprises an elastic member, a linkage rod, and an operating member, one of two ends of the linkage rod leans against the elastic member and is normally locked to the liquid cooling plate, the other end of the linkage rod is connected to the operating member, and a portion between the two ends of the linkage rod is pivotally connected to the rail; in response to a linear displacement of the operating member, the linkage rod is driven to be pivotally rotated, so that the end of the linkage rod is not locked to the liquid cooling plate, allowing the liquid cooling plate to selectively slide on the slide rail component.

5. The liquid cooling testing device according to claim 4, wherein the elastic member is a compression spring, and the linkage rod is an L-shaped rod; the linkage rod comprises a first body section, a second body section, and a bent portion, the first body section is connected to the operating member, one of two ends of the elastic member leans against the rail, and the other end of the elastic member leans against the second body portion of the linkage rod; the bent portion is pivotally connected to the rail.

6. The liquid cooling testing device according to claim 2, wherein the slide rail component comprises a first rail and a second rail; the liquid cooling plate further comprises a first supporting section and a second supporting section; the liquid inlet is at the first supporting section, and the liquid outlet is at the second supporting section; the first supporting section selectively slides on the first rail, and the second supporting section selectively slides on the second rail.

7. The liquid cooling testing device according to claim 6, wherein at least one of the first rail and the second rail comprise a supporting portion; at least one of the first supporting portion and the second supporting portion further comprises a positioning portion; the supporting portion and the positioning portion are adapted to support a disassembly tool to disassemble the liquid cooling plate.

8. The liquid cooling testing device according to claim 7, wherein the disassembly tool comprises a handle, a fixed arm, a first hook arm, and a second hook arm; the handle is fixed on the fixed arm; one of two ends of the first hook arm and one of two ends of the second hook arm are pivotally connected to the fixed arm, respectively; the other end of the first hook arm is adapted to be engaged with the supporting portion, and the other end of the second hook arm is adapted to be engaged with the positioning portion.

9. The liquid cooling testing device according to claim 8, wherein the first hook arm comprises two hook portions; the two hook portions are at two opposite sides of the first hook arm to be engaged with the supporting portion selectively. ; the second hook arm comprises a slot and an abutting block; the slot is at one end of the second hook arm away from the fixed arm, and the slot is adapted to be engaged with the positioning portion; the abutting block is between the two ends of the second hook arm, and the abutting block is adapted to push against the liquid cooling plate.

10. The liquid cooling testing device according to claim 1, further comprising a flow detection module, wherein the flow detection module is disposed between the liquid-input coupling member and the liquid-output coupling member to monitor the flow of the cooling liquid.

11. The liquid cooling testing device according to claim 10, further comprising a liquid inlet port and a liquid outlet port, wherein the flow detection module comprises a first flowmeter and a second flowmeter; the first flowmeter is disposed between the liquid inlet port and the liquid-input coupling member, and the second flowmeter is disposed between the liquid outlet port and the liquid-output coupling member.

12. The liquid cooling testing device according to claim 11, further comprising a controller and a power supply, wherein the controller is connected to the first flowmeter, the second flowmeter, and the power supply.

13. The liquid cooling testing device according to claim 1, further comprising a first blocking member and a second blocking member, wherein the first blocking member is disposed between the liquid-input coupling member and the liquid cooling plate, and the second blocking member is disposed between the liquid-output coupling member and the liquid cooling plate.

14. The liquid cooling testing device according to claim 1, wherein the liquid cooling plate further comprises a first guide hole; the liquid-input coupling member comprises a first guide pin and a first connection portion; the first guide pin and the first connection portion respectively extend from the liquid-input coupling member along a first direction; a length of the first guide pin along the first direction is greater than a length of the first connection portion along the first direction; when the liquid cooling plate is accommodated in the slide rail component, the first guide hole is coupled to the first guide pin, and the liquid inlet is coupled to the first connection portion.

15. The liquid cooling testing device according to claim 1, wherein the liquid cooling plate further comprises a second guide hole; the liquid-output coupling member comprises a second guide pin and a second connection portion; the second guide pin and the second connection portion respectively extend from the liquid-output coupling member along the first direction; a length of the second guide pin along the first direction is greater than a length of the second connection portion along the first direction; when the liquid cooling plate is accommodated in the slide rail component, the second guide hole is coupled to the second guide pin, and the liquid outlet is coupled to the second connection portion.
